(19) United States
(12) Patent Application Publication
(10) Pub. No.: US 2017/0081757 A1
(43) Pub. Date: Mar. 23, 2017

(54) SHADOW FRAME WITH NON-UNIFORM GAS FLOW CLEARANCE FOR IMPROVED CLEANING

(71) Applicant: Applied Materials, Inc., Santa Clara, CA (US)

(72) Inventors: Shinichi KURITA, San Jose, CA (US); Robin L. TINER, Santa Cruz, CA (US)

(21) Appl. No.: 15/136,518

(22) Filed: Apr. 22, 2016

Related U.S. Application Data
(60) Provisional application No. 62/222,731, filed on Sep. 23, 2015.

(51) Int. Cl. C23C 16/04; H05K 7/20; C23C 16/455; H05K 7/18

(52) U.S. Cl. CPC C23C 16/042; H05K 7/18; H05K 7/20; C23C 16/45502

(57) ABSTRACT

The embodiments described herein generally relate to a frame for use in a plasma processing chamber to provide non-uniform gas flow flowing between the frame and sidewalls of the plasma processing chamber. In one embodiment, a frame includes a frame body having an inner wall and an outer wall defining a frame body, a center opening formed in the frame defined by the inner wall, and a corner region and a center region formed in a first side of the frame body. The corner region having a corner width that is smaller than a center width of the center region, wherein the widths are defined between the inner and outer walls.

### CROSS-REFERENCE TO RELATED APPLICATIONS

This application claims benefit of U.S. Provisional Application Ser. No. 62/222,731 filed Sep. 23, 2015 (Attorney Docket No. APPM/23331L), which is incorporated by reference in its entirety.

### BACKGROUND OF THE INVENTION

Field of the Invention

Embodiments disclosed herein generally relate to an apparatus for fabricating films on substrates in a processing chamber, more particularly, for a frame used in a processing chamber to provide non-uniform gas flow for plasma processing applications.

Description of the Related Art

Liquid crystal displays or flat panels are commonly used for active matrix displays, such as computer, television, and other monitors. Plasma enhanced chemical vapor deposition (PECVD) is used to deposit thin films on a substrate, such as a semiconductor wafer or a transparent substrate for a flat panel display. PECVD is generally accomplished by introducing a precursor gas or gas mixture into a vacuum chamber containing a substrate. The precursor gas or gas mixture is typically directed downwardly through a distribution plate situated near the top of the processing chamber. The precursor gas or gas mixture in the processing chamber is energized (e.g., excited) into a plasma by applying a power, such as a radio frequency (RF) power, to an electrode in the processing chamber from one or more power sources coupled to the electrode. The excited gas or gas mixture reacts to form a layer of material on a surface of the substrate. The layer may be, for example, a passivation layer, a gate insulator, a buffer layer, and/or an etch stop layer. The layer may be a part of a larger structure, such as, for example, a thin film transistor (TFT) or an active matrix organic light emitting diodes (AMOLED) used in a display device.

Flat panels processed by PECVD techniques are typically large. For example, the flat panel may exceed 4 square meters. During processing, the edge and backside of the glass substrate as well as the internal chamber components must be protected from deposition. Typically, a deposition masking device, such as a shadow frame, is placed about the periphery of the substrate to prevent processing gases or plasma from reaching the edge and backside of the substrate and to hold the substrate on a support member during processing. The shadow frame may be positioned in the processing chamber above the support member so that when the support member is moved into a raised processing position, the shadow frame is picked up and contacts an edge portion of the substrate. As a result, the shadow frame covers several millimeters of the periphery of the upper surface of the substrate, thereby preventing edge and backside deposition on the substrate.

With consideration of the benefits of using a shadow frame, there are a number of disadvantages. For example, during a deposition process, processing gases supplied into the processing chamber may not only flow into the processing region, but also flow through other regions, such as the regions close to the substrate edge, chamber wall and the shadow frame, resulting in undesired gas distribution profile during the deposition process, which may affect the deposition uniformity and defect rates. Furthermore, flow patterns caused by standard shadow frames may affect the cleaning uniformity and efficiency, and may impact removal film deposits, cause flaking or over-clean and erode chamber component during cleaning processes.

Therefore, there is a need for an improved frame structure for utilizing in a processing chamber.

### SUMMARY

The embodiments described herein generally relate to a frame for use in a plasma processing chamber that provides non-uniform gas flow between the frame and sidewalls of the plasma processing chamber. In one embodiment, a frame includes a frame body having an inner wall and an outer wall defining a frame body, a center opening formed in the frame defined by the inner wall, and a corner region and a center region formed in a first side of the frame body. The corner region having a corner width that is smaller than a center width of the center region, wherein the widths are defined between the inner and outer walls.

In another embodiment, a processing chamber includes a chamber body comprising a top wall, sidewall and a bottom wall defining a processing region in the chamber body, a substrate support positioned in the processing region, and a frame circumscribing substrate support, wherein a gap between an outer wall of the frame and the sidewall of the chamber body is narrower near a center region of the outer wall.

In yet another embodiment, a method of controlling a non-uniform gas flow in a processing chamber includes directing a gas flow flowing from a corner gap and a center gap defined between a frame and a sidewall of a processing chamber into a processing region defined in the processing chamber, wherein the gas flow has a first flow rate flowing through the corner gap that is greater than a second flow rate through the center gap.

### BRIEF DESCRIPTION OF THE DRAWINGS

So that the manner in which the above recited features of the present invention can be understood in detail, a more particular description of the invention, briefly summarized above, may be had by reference to embodiments, some of, which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a cross-sectional view of a processing chamber with a frame disposed therein according to one embodiment;

FIGS. 2A-2C depict top view of different examples of frames utilized in a processing chamber;

FIGS. 2AA-2AC depict cross sectional view of different examples of frames located above or close to a substrate support assembly utilized in a processing chamber;

FIGS. 3A-3C depict pressure profile maps utilizing different examples of the frame of FIGS. 2A-2C; and

FIGS. 4A-4C depict gas flow velocity maps utilizing different examples of the frame of FIGS. 2A-2C; and

FIG. 5A depicts a top view of the frame of FIG. 2B;

FIG. 5B depicts a top view of another example of a frame; and

FIG. 6A-6B depict another example of a substrate support disposed in a processing chamber.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to a frame with various outer perimeter geometries configured to alter the gas flow path along edge regions and across an upper surface of the substrates when positioned in a processing chamber. The outer perimeter geometry of the frame may be selected to control the gas flow path, gas flow rate, gas flow velocity and process gas velocity passing between the frame and the chamber wall so that the deposition profile, etching profile or cleaning profile resulting from deposition, etch, or cleaning processes performed in the processing chamber may be efficiently controlled.

Embodiments herein are illustratively described below in reference to a PECVD system configured to process large area substrates, such as a PECVD system, available from AKT America, Inc., a division of Applied Materials, Inc., located in Santa Clara, Calif. However, it should be understood that the disclosed frame has utility in other system configurations such as etch systems, other chemical vapor deposition systems, and other plasma processing systems. It should further be understood that embodiments disclosed herein may be practiced using process chambers provided by other manufacturers.

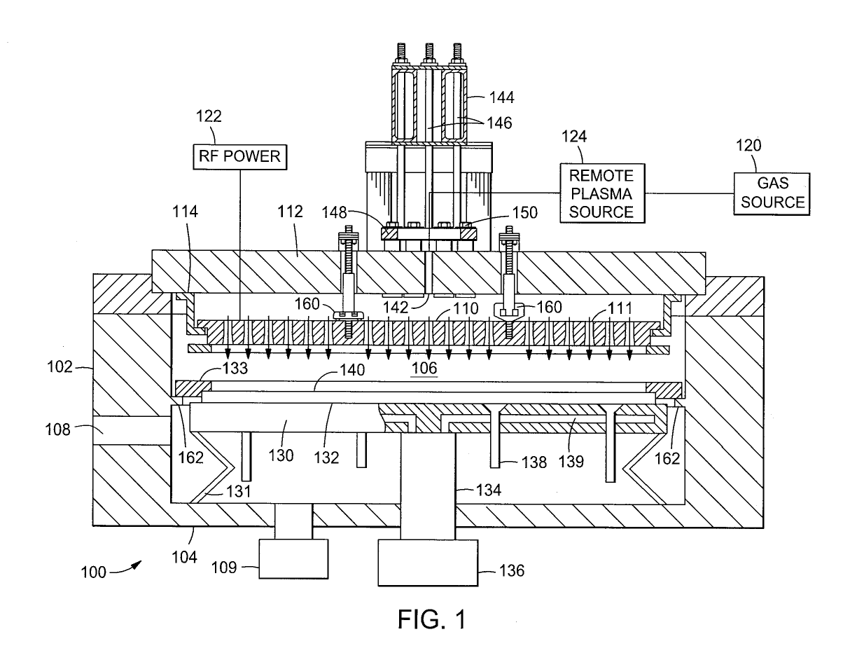

FIG. 1 is a cross sectional view of PECVD apparatus according to one embodiment. The apparatus includes a vacuum processing chamber 100 in which one or more films may be deposited onto a substrate 140. The apparatus may be used to process one or more substrates, for example, semiconductor substrates, flat panel display substrates, and solar panel substrates, among others.

The processing chamber 100 generally includes sidewalls 102, a bottom 104 and a showerhead 110 that define a processing volume 106. A substrate support (or susceptor) 130 is disposed in the processing volume 106. The substrate support 130 includes a substrate receiving surface 132 for supporting the substrate 140. The process volume 106 is accessed through an opening 108 formed through the sidewalls 102 such that the substrate 140 may be transferred in and out of the chamber 100 when the substrate support 130 is in the lowered position. One or more stems 134 may be coupled to a lift system 136 to raise and lower the substrate support 130. As shown in FIG. 1, the substrate is in a lowered position where the substrate 140 can be transferring into and out of the chamber 100. The substrate 140 can be elevated to a processing position, not shown, for processing. The spacing between the top surface of the substrate 140 disposed on the substrate receiving surface 132 and the showerhead 110 may be between about 400 mil and about 1,200 mil when the substrate support 130 is raised to the processing position. In one embodiment, the spacing may be between about 400 mil and about 800 mil.

Lift pins 138 are moveably disposed through the substrate support 130 to space the substrate 140 from the substrate receiving surface 132 to facilitate robotic transfer of the substrate. The substrate support 130 may also include heating and/or cooling elements 139 to maintain the substrate support 130 at a desired temperature. The substrate support 130 may also include RF return straps 131 to provide a RF return path at the periphery of the substrate support 130.

The showerhead 110 may be coupled to a backing plate 112 at its periphery by a suspension 114. The showerhead 110 may also be coupled to the backing plate 112 by one or more coupling supports 160 to help prevent sag and/or control the straightness/curvature of the showerhead 110.

A gas source 120 may be coupled to the backing plate 112 to provide processing gas through a gas outlet 142 in the backing plate 112 and through gas passages 111 in the showerhead 110 to the substrate 140 disposed on the substrate receiving surface 132. A vacuum pump 109 may be coupled to the chamber 100 to control the pressure within the process volume 106. An RF power source 122 is coupled to the backing plate 112 and/or to the showerhead 110 to provide RF power to the showerhead 110. The RF power creates an electric field between the showerhead 110 and the substrate support 130 so that a plasma may be generated from the gases between the showerhead 110 and the substrate support 130. Various frequencies may be used, such as a frequency between about 0.3 MHz and about 200 MHz. In one embodiment, the RF power source is provided at a frequency of 13.56 MHz.

A remote plasma source 124, such as an inductively coupled remote plasma source, may also be coupled between the gas source 120 and the backing plate 112. Between processing substrates, a cleaning gas may be provided to the remote plasma source 124 so that a remote plasma is generated and provided into the processing volume 106 to clean chamber components. The cleaning gas may be further excited while in the processing volume 106 by power applied to the showerhead 110 from the RF power source 122. Suitable cleaning gases include but are not limited to NF₃, F₂, and SF₆.

A frame 133 may be placed adjacent to the periphery region of the substrate 140, either in contact with or spaced from the substrate 140. In some embodiments, the frame 133 may be configured to be disposed under the substrate 140. In other embodiments, the frame 133 may be configured to be disposed over the substrate 140. The frame 133 may be a shadow frame, a non-contact frame (e.g., the frame is not in contact with a substrate when positioned on the substrate support 130), a floating frame, a removable frame, a confinement ring, a flow control structure, or other suitable structure positionable adjacent the periphery of the substrate 140.

In the embodiment depicted in FIG. 1, the frame 133 may rest on a frame support 162 when the substrate support 130 is lowered to provide clearance for the substrate 140 being placed on or removed from the substrate support 130. In one embodiment, the frame support 162 may comprise the same material as the chamber sidewalls 102. In another embodiment, the frame support 162 may comprise a conductive material, dielectric material, stainless steel or aluminum. The frame 133 may reduce deposition at the edge of the substrate 140 and on areas of the substrate support 130 that are not covered by the substrate 140. When the substrate support 130 is elevated to the processing position, the frame 133 may engage the substrate 140 and/or substrate support 130, and be lifted off of the frame support 162.

During the cleaning process, the frame 133 may rest on the frame support 162. The substrate receiving surface 132 may also be raised to a level that touches the frame 133 without lifting the frame 133 off from the frame support 162 during cleaning.

The substrate support 130 has an outer profile. In some embodiments, the frame 133 or portions thereof, when seated on the substrate support 130, may extend beyond portions of the perimeter of the substrate support 130, and as such, define of the outer profile of the periphery of the substrate support 130. The amount of open area between the substrate support 130 and sidewalls of the processing chamber 100 controls the amount of gas passing by the substrate support 130 and substrate 140 positioned thereon. Thus, by preferentially having more open area proximate one region of the substrate support 130 relative to another region, the amount of gas flowing by one region of the substrate support 130 and substrate 140 relative to another may be controlled. For example, the open area proximate a center region of the substrate support 130 may be different than the open area proximate a corner region of the substrate support 130, thus preferentially directing more flow through the area with more open area. Preferentially directing more flow to one region may be utilized to compensate for other conductance asymmetries to produce a more uniform flow across the substrate, or to cause more gas to flow over one region of the substrate relative another. In one example, flow may be preferentially directed to a center region of the substrate support 130 relative to a corner region. In another example, flow may be preferentially directed to a corner region of the substrate support 130 relative to a center region. In another example, flow may be preferentially directed to one side of the substrate support 130 relative to another side. The open area on a side of the substrate support 130 may be selected by selecting the geometry of the profile of the substrate support 130 to control the width across a gap between the profile of the substrate support 130 and sidewall of the processing chamber 100, such as the curvature of the perimeter of the substrate support 130 and/or frame 133; and/or selecting a diameter and/or number of apertures formed through the frame 130, as further discussed below.

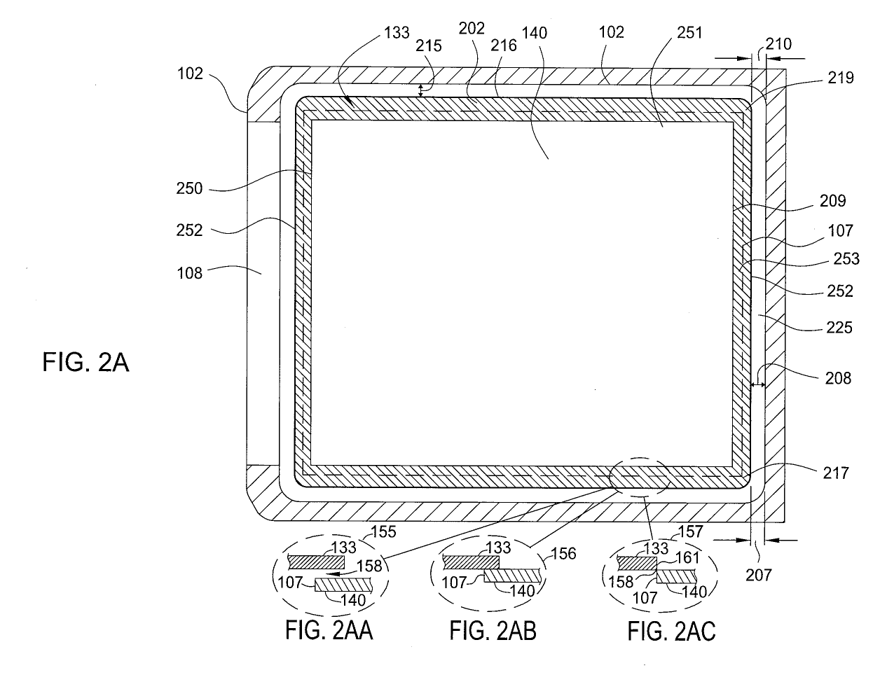

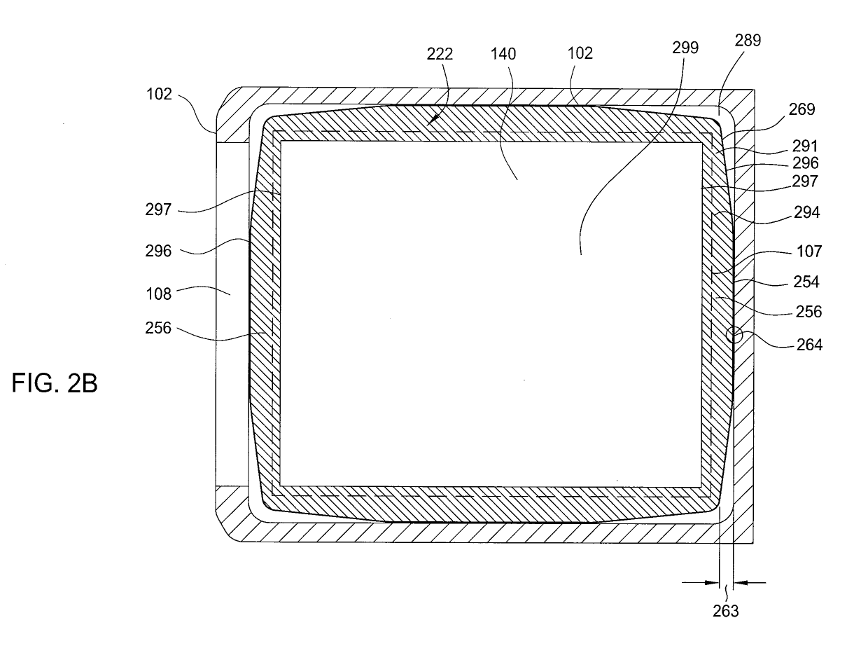

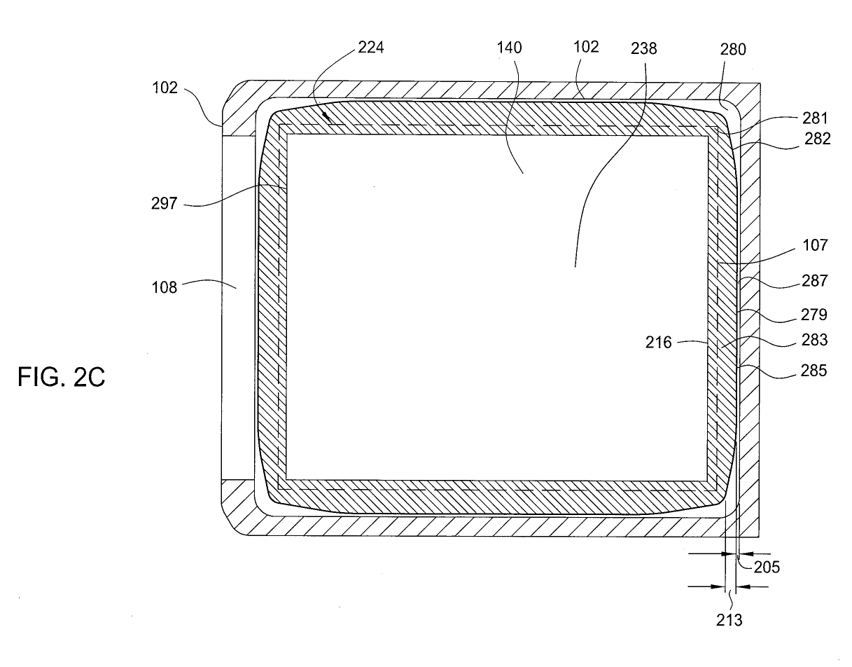

FIG. 2A depicts a top view of the frame 133 that may be utilized in a processing chamber, such as the processing chamber 100 depicted in FIG. 1. The frame 133 includes a frame body 202. The frame body 202 has an inner wall 250 and an outer wall 252 that defines the frame body 202 in a substantially square/rectangular form.

The inner wall 250 of the frame body 202 defines a center opening 251 that slightly covers a periphery region 107 of the substrate 140. The inner wall 250, and hence also the center opening 251, has a quadrilateral form. The inner wall 250 of the frame body 202 may be sized to be in close proximity to (e.g., in contact with or spaced a determined distance inside of) an edge region 209 of the substrate 140.

In one example, the frame 133 may be positioned above (e.g., non-contact with) the periphery region 107 (e.g., the edge region 209) of the substrate 140, as shown in a cross sectional view, as indicated by the circle 155, in FIG. 2AA. The frame 133 disposed above (e.g., non-contact with) the substrate 140 may defines a gap 158 between the frame 133 and the substrate 140 that allows gas to flow therethrough. Alternatively, the frame 133 may be positioned in contact with the periphery region 107 (e.g., the edge region 209) of the substrate 140, as indicated by the circle 156 shown in FIG. 2AB, thus leaving no gap therebetween. In yet another example, the frame 133 may positioned right above the substrate 140 with a bottom corner 161 in contact with a top corner 158 of the substrate 140, as indicated by the circle 157 shown in FIG. 2AC, thus leaving no gap therebetween. It is noted that the relatively positional relationship between the substrate 140 and the frame 133 may be in any arrangement as needed. In the embodiment depicted in FIGS. 2A, 2B and 2C, the frame 133, 222, 224 is positioned above the substrate 140, as shown in the dotted line of the substrate 140, with or without in contact with the substrate 140, as depicted in the examples of FIGS. 2AA and 2AB.

Referring back to the example depicted in FIG. 2A, the outer wall 252 of the frame 133 has a substantially straight profile that is in a spaced-apart relationship with the sidewall 102 of the processing chamber 100, which defines a gap 225 between the four sides of the frame 133 and the sidewall 102 of the processing chamber 100. The gap 225 between a center region 253 of the frame 133 and the sidewall 102 of the processing chamber 100 may have a predetermined width 215, 208, that is in some embodiments, greater than about 40 mm. As the outer walls 252, 216 of the center region 253 of the frame 133 are configured to be substantially straight, the widths 215, 208 between the four sides of the outer walls 252, 216 of the frame 133 and the sidewalls 102 of the processing chamber 100 may be equal. For example, the widths 215, 208 between the outer wall 216 and/or the outer wall 252 and the sidewall 102 of the processing chamber 100 respectively may be substantially the same. Furthermore, as the outer walls 216, 252 of the frame 133 are configured to be substantially straight, a first width 207 and a second width 210 defined from a first corner 217 of the frame 133 to a second corner 219 along the sidewall 102 of the processing chamber 100 are substantially the same as the width 208, 205 defined in the center region 253 of the frame 133.

It is noted that the terms or phrases “corner” or “corner region” as described herein represents the area bounded in part by interesting sides of the frame and extending less than about one fourth of the length of each of the sides in a direction away from their intersection. The terms or phrases “center” or “center region” as described herein represents a portion of a side which includes a center point of the side and bounded by two adjacent corner regions (for example about one third to one half of the total length of a side of the frame).

FIG. 2B depicts another example of a frame 222 that may be utilized in a processing chamber, such as the processing chamber 100 depicted in FIG. 1. Similar to the frame 133 depicted in FIG. 2A, the frame 222 of FIG. 2B has a frame body 294 having a center opening 299 defined by an inner wall 297 of the frame 222. The opening 299 is sized to allow the substrate 140 to be positioned therein just slightly overlapped by the inner wall 297 of the frame 222, as shown in the dotted line of the substrate 140.

The frame 222 further includes an outer wall 296 opposite the inner wall 297 defining an outer perimeter of the frame body 294. In one example, the outer wall 296 of the frame 222 may be non-linear. For example, the outer wall 296 may have a curvature (e.g., bow) defined by a center region 256 being in close proximity to (e.g., a width 264 less than 10 mm) the sidewall 102 of the processing chamber 100. The center region 256 may define a first surface 254 having a first curvature.

A corner region 291 of the outer wall 296 is positioned farther away from the sidewall 102 of the processing chamber 100 relative to the center region 256, thus forming a corner gap 289 between the corner region 291 and the sidewall 102 of the processing chamber 100. A second surface 269 having a second curvature may be formed at the corner region 291 of the outer wall 296 of the frame 222. The curved second surface 269 is configured to have the greater curvature (i.e., radius) greater than the curvature of the first surface 254. In some examples, the first surface 254 in the center region 256 may be configured to have a minimal to zero curvature (e.g., be substantially linear across the center region 256) for ease of matching the frame 222 with the sidewall 102 of the processing chamber 100 with a minimal gap formed therebetween.

It is believed that the further spacing of the corner region 291 of the frame 222 relative to the center region 256 will preferentially direct more processing gases to the corners of the substrate relative to the edge of the substrate. The additional gas flow passing through the corner gap 289 defined between the frame 222 and the sidewall 102 relate to the center gap (not shown in FIG. 2B) may alter the gas flow path flowing across a surface of the substrate 140. The geometry of the outer wall 254 may affect the width 264, 263 and dimensions of the corner gap 289 as well as the center gap formed between the sidewall 102 and the center and corner regions 256, 291 of the frame 222, thus providing a controllable choked flow of the gases passing between the frame 222 and the sidewall 102. It is believed that the difference in the flow of the gases flowing through the corner gap 289 relative to the center gap may create a flow gradient of process gases across the upper surface of the substrate 140, which may be beneficial for certain deposition processes. By utilizing a larger corner gap 289 formed at corner region 291 relative to the center gap from in the center region 256, the flow through the corner gap 289 may be increased. Thus, the geometry of the outer wall 296 may be selected to control the size/dimension of the corner gap 289 relative to center gap, thus enabling the corner gas flow to be controlled relative to the center gas flow. Non-uniform dimensions of the gaps formed in the center and corner regions 256, 291 of the frame 222 with the sidewall of the processing chamber 100 may efficiently alter the gas flow distribution across the substrate surface. As different conductance of the choked flow results in different amounts of processing gases to reach different areas of the substrate, the film profile, film properties and film thickness deposited on the surface of the substrate 140 may be controlled. The same flow control provided during deposition by the frame 222 also allows the cleaning efficiency to be controlled across different areas of the processing chamber 100 during the cleaning process.

It has been discovered that by having a predetermined size/dimension ratio of the corner gap 289 relative to the center gap, film properties/cleaning uniformity can be adjusted. As further depicted in FIG. 2C, a center gap 287 may be defined between the sidewall 102 and a frame 224 with a relatively linear surface 279 formed as an outer wall 285 in a center region 283 of the frame 224. A relatively curved surface 282 may be formed at a corner region 281 of the outer wall 285 of the frame 224. The center gap 287 may have a width 205 between about 10 mm and about 40 mm. As the geometry of the outer wall 285 has different curvatures at different regions (e.g., the center and the corner regions 283, 281), the center gap 287 and the corner gap 280 defined between the frame 224 and the sidewall 102 will have different widths, thus allowing greater gas flow at the corner regions 283, 281. As a result, the higher corner gas flow alters the gas flow path/profile across the upper surface of the substrate 140, which changes the deposition/cleaning properties.

Similarly, a center opening 238 is defined by an inner wall 297 of the frame 224. The center opening 238 may allow the substrate 140 to be positioned therein, and slightly overlapped by the inner wall 297 of the frame 224.

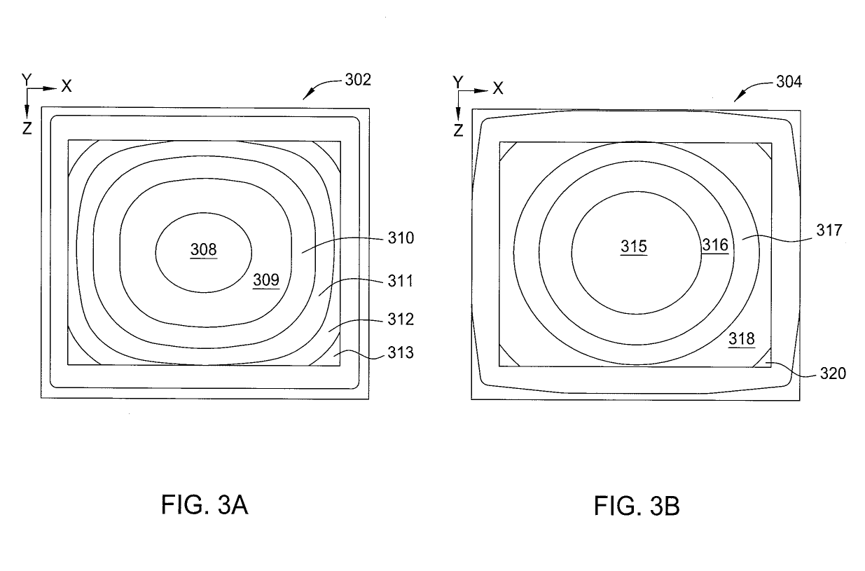

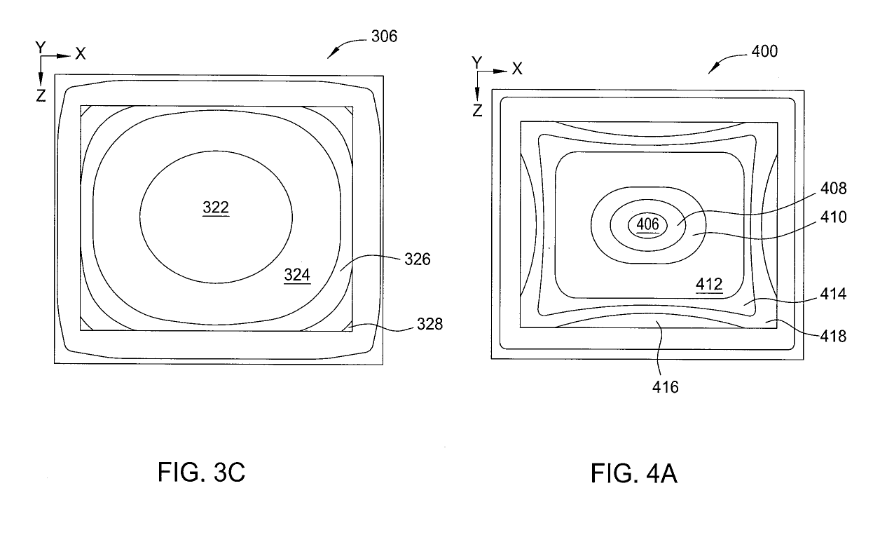

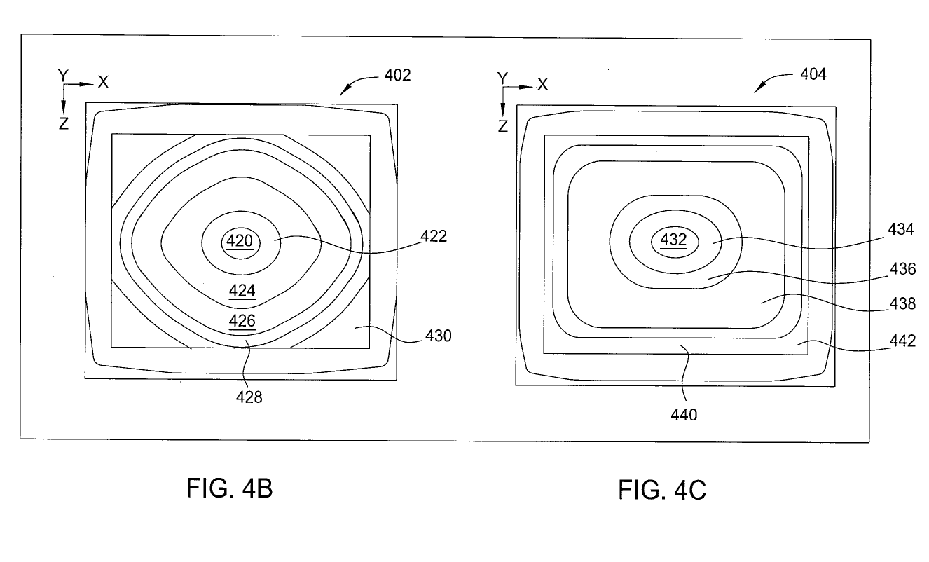

FIGS. 3A-3C depict pressure profile maps 302, 304, 306 and FIGS. 4A-4C depict gas flow velocity profile maps 400, 402, 404 detected above a substrate surface utilizing the frames 133, 222, 224 with different configurations from FIGS. 2A-2C respectively. As depicted in FIG. 3A with the frame 133 having the relatively straight outer wall 252 (having a center and edge gap with the uniform width 208, 215, 207, 210 greater than 40 mm), the pressure profile as shown on the map 302 may have a relatively high pressure in the center regions 308, 309 and a relatively low pressure at the edge regions 310, 311, 312, with particularly low pressure at the corners 313 (e.g., center high pressure and edge low pressure). In this example, a pressure gradient (e.g., the pressure variation calculated by subtracting the lowest pressure at the corner region 313 from the highest pressure in the center region 308) may be controlled at around 0.1-0.2 Torr to maintain a center high pressure to a corner low pressure profile.

Furthermore, the gas flow velocity maps depicted in FIGS. 4A-4C, it illustrate that the variation of gas flow velocity across the substrate surface is also correlated to the different configurations of the frames 133, 222, 224. In the gas flow velocity map 400 depicted in FIG. 4A utilizing the frame 133 with substantially relatively straight outer wall 252, the gas flow velocity is relatively low in the center region 406 while relatively high in the corner region 418 and the edge region 416. Particularly, the gas flow velocity at the edge region 416 is even higher than the gas flow velocity at the corner region 418 by about 15% to about 20%. In the example depicted in FIG. 4A, the gas flow velocity has a gradient profile, from a low velocity in the center, gradually ramping up to a high edge velocity (e.g., with the lowest velocity in the center region 406, and gradually to higher velocity in regions 410, 412, 414, and then an even higher velocity at the corner region 418 and the highest velocity at the edge region 416).

In another example depicted in FIGS. 3B and 4B with the frame 222 depicted in FIG. 2B, the pressure profile map 304 and the gas flow velocity profile map 402 indicate that the frame 222 with a relatively high corner flow (e.g., with minimum gap width 264 less than 10 mm formed in the center region 256 of the frame 222 against the sidewall 102) may have the highest pressure in the center region 315 and the lowest gas flow velocity in the corner region 320. Similarly, the pressure gradually reduces from the center regions 316, 317 to the corner regions 318, 320. The pressure gradient (e.g., the pressure variation calculated by subtracting lowest pressure at the corner region 320 from the highest pressure in the center region 315) may be around 0.1-0.2 Torr from the center high pressure to the corner low pressure.

Furthermore, as the corner flow is enhanced by the corner gap 289 formed by the frame 222 of FIG. 2B, the pressure at the center region 315 is higher than the pressure of the center region 308 of FIG. 3A utilizing the frame 133 of FIG. 2A without enhanced corner flow. In one example, the pressure in the center region 315 of FIG. 3B may be around 1.46-1.48 Torr, while the pressure in the center region 308 of FIG. 3A may be around 1.41-1.42 Torr, which is about 3% to 5% higher pressure than the process without enhanced corner flow.

In contrast, the lowest gas flow velocity is found in the center region 420 and then gradually increased from the center regions 422, 424, 426 to the edge regions 428 and with the highest gas flow velocity at the corners 430, as shown in FIG. 4B. As discussed above, as the frame 222 with the corner gap 289 has enhanced corner gas flow, the highest gas flow velocity at the corners 430, while the lowest gas flow velocity is in the center region 420. In comparing with the gas flow velocity map 402 of FIG. 4B with the map 400 in FIG. 4A (e.g., utilizing the frame 133 without enhanced corner flow), the gas flow velocity at the corner region 430 with the enhanced corner flow from the frame 222 may have a velocity around 8-9 m/s (meters per second), while the gas flow velocity in the corner region 418 without enhanced corner flow may be around 6-6.5 m/s, which is about 20% lower gas flow velocity. Thus, by utilizing frame 222, the pressure profile and the gas flow velocity profile across the substrate surface may be adjusted to efficiently improve deposition uniformity and profile control during a deposition process, and/or to enhance cleaning efficiency during a chamber cleaning process.

Furthermore, in contrast to the maps 302, 304, 400, 402 without or with the enhanced corner gas flow, the frame 244 of FIG. 2C provides an intermediate pressure gradient and gas flow velocity gradient, as shown in the maps 306, 404 of FIGS. 3C and 4C. As the frame 244 of FIG. 2C also provides the center gap 287 with reduced width 205 of less than 10 mm (as compared to the width 208 of greater than 40 mm defined by the gap 225 from the frame 133), the choked gas flow may not only flow through the corner gap 280, but also through the center gap 287. Thus, the degree of the flow being preferentially directed through the corner region 219 by the frame 133 of FIG. 2A may not be as significant as the gas flow through the corner gap 289 by the frame 222 of FIG. 2B. Thus, by adjusting the sizes/dimensions of the gap formed in the center region between the frame and the sidewall of the processing chamber, the amount of gas flow preferentially directed to the corners relative to the middle edge of the substrate may be adjusted, so as to obtain different deposition profiles and cleaning efficiency as needed.

The pressure profile map 306 of FIG. 3C illustrates that the frame 224 with the center gap 287 that still allows a small amount of gas flow passing therethrough (e.g., with reduced center gap width 205 between 10 mm and 40 mm as compared to the width 208 of greater than 40 mm of FIG. 2A), the highest pressure is found in the center region 322 and the lowest pressure in the corner region 328. The pressure gradually reduces from the center regions 322, 324, 326 to the corner region 328. The pressure gradient (e.g., the pressure variation calculated by subtracting the lowest pressure at the corner region 328 from the highest pressure in the center region 322) may be around 0.1-0.2 Torr from the high pressure center to the edge/corner low pressure corner.

The pressure profile map 306 of FIG. 3C is relatively similar to the pressure profile map 302 of FIG. 3A. The pressure in the region 322 is about 1.42 Torr, which is similar to the pressure in the center region 308 of FIG. 3A.

In contrast, according to the gas flow velocity map 404 of FIG. 4C, the lowest gas flow velocity is found in the center region 432, and gradually increases from the center regions 434, 436, 438, 440 to the highest gas flow velocity similarly both at the edge region 440 and at corner region 442, as shown in FIG. 4C. As the corner gas flow caused by the frame 224 of FIG. 2C is not great as much as the corner gas flow caused by the frame 222 of FIG. 2B, the gas flow velocity generated at the corner region 442 and the edge region 440 tends to be similar, for example with a tight range of around 6-6.5 m/s, thus providing a more uniform gas flow velocity around the periphery region 107 of the substrate 140. Thus, in the embodiment where a uniform gas flow velocity is desired at both the center region and the edge region of the substrate, the frame 224 of FIG. 2C with the reduced gap dimension 205 of between 10 mm and about 40 mm may be desirable.

In an example where a silicon nitride is deposited on the substrate, the frame 222 of FIG. 2B may be utilized to enhance gas flow preferentially to the corner relative to the edges of the substrate, which enhances the silicon nitride deposition at the corners of the substrate. In another example where a silicon oxide or polysilicon (e.g., low temperature polysilicon (LTPS)) deposition process is performed, the frame 224 of FIG. 2C may be utilized to provide a more uniform gas flow velocity at both the edge and corner regions of the substrate.

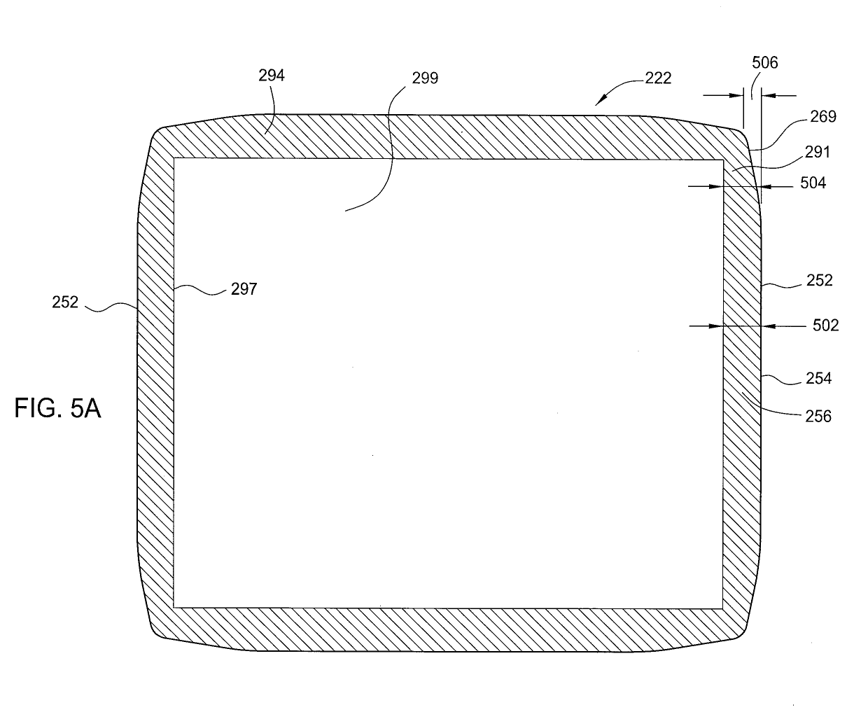

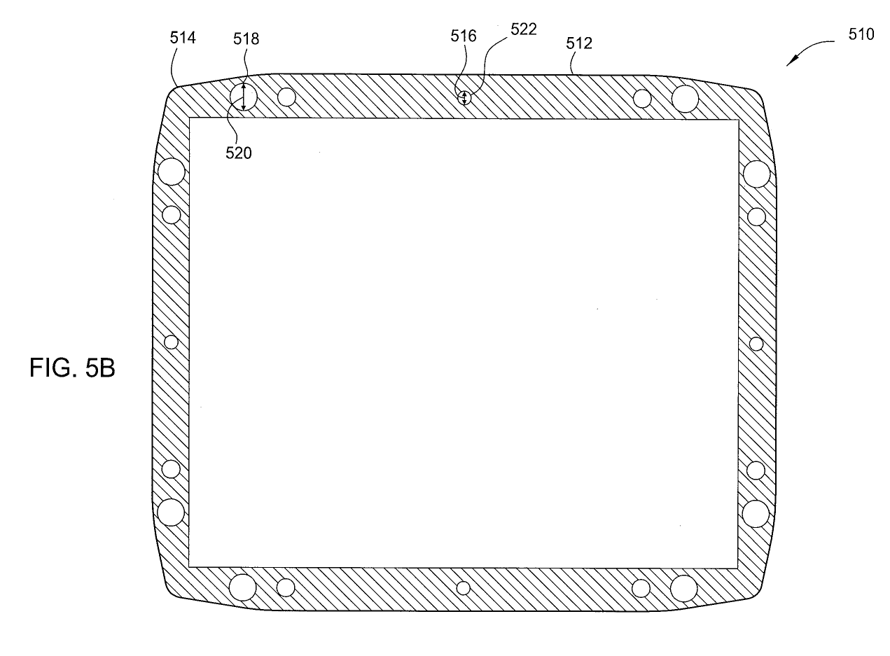

FIG. 5A depicts a top view of the frame 222 of FIG. 2B. As discussed above, the frame 222 has the outer wall 252 and the inner wall 297 defining the frame body 294. The inner wall 297 defines a substantially quadrilateral opening, such as a rectangle or square. The corner region 291 of the frame 222 has the second surface 269 with the second curvature. The center region 256 has the first surface 254 that can have linear or non-linear profile as needed. In the embodiment depicted in FIG. 5, the first surface 254 in the center region 256 is substantially in linear configuration. In some examples, the first surface 254 may be curved with the first curvature. In such circumstances, the first curvature defined by a radius of the first surface 254 is less than a radius if the second curvature defined by the second surface 269. In one example, the second curvature is between about 30% to about 90% greater than the first curvature.

The frame body 294 has a center body width 502 between about 5 mm and about 1000 mm in the center region 256 and a corner body width 504 between about 10 mm and about 1500 mm in the corner region 291. In one example, the corner body width 504 is between about 30% and about 90% shorter than the center body width 502 of the frame body 294. Furthermore, a total width deviation 506 (i.e., the differences between the widths 502, 504) for one side of the frame body 294 from the center region 256 to the corner region 291 is between about 5 mm and about 60 mm along one side of the frame 222. In one embodiment, the frame 222 is rectangular.

Similarly constructed, the frame 224 of FIG. 2C has the relatively linear surface 279 formed in the center region 283 with less curvature than the curved surface 282 formed in the corner region 281. However, as the frame 224 of FIG. 2C is configured to still maintain the gap 287 (of between about 10 mm and about 40 mm) between the sidewall 102 and the frame 224 when positioned in the processing chamber 100, the variation in width of the frame body 294 between the corner region 281 and the center region 283 may not be as large as that of the frame 222 of FIG. 2B. For example, a total width deviation 213 alone one side of the frame 224 of FIG. 2C from the center region 283 to the corner region 281 is between about 5 mm and about 40 mm. The center region 283 of the frame 224 of FIG. 2C may have a width about 35% and about 85% greater than a width in the corner region 281.

FIG. 5B depicts another example of a frame 510 with different size apertures 522, 518 formed in the frame 510 for creating a flow gradient around different regions of the frame 510. For example, the frame 510 may have apertures 518, 522 formed in a corner region 514 and center region 512 of the frame 510 respectively. In order to have different flow rates at different regions of the frame 510, the amount of open area provided by the apertures 522, 518 may be varied. The open area may be varied by selecting the number and/or sizes of the apertures 522, 518. In one example, the aperture 518 located in the corner region 514 of the frame 510 may have a diameter 520 greater than a diameter 516 of the aperture 522 located at the center region 512 of the frame 510 so that the flow is greater at the corner region 514 relative to the center region 512. The diameter 520 of the aperture 518 located in the corner region 514 is between about 30% and about 90% greater than the diameter 516 of the aperture 522 located in the center region 512. In other embodiments, the number, and optionally also the diameters, of apertures 522, 518 may be selected to have 30% and about 90% greater flow at the corner region 514 relative to the center region 512. Alternatively, the open area of the apertures 522, 518 may be selected to have 30% and about 90% less flow at the corner region 514 relative to the center region 512.

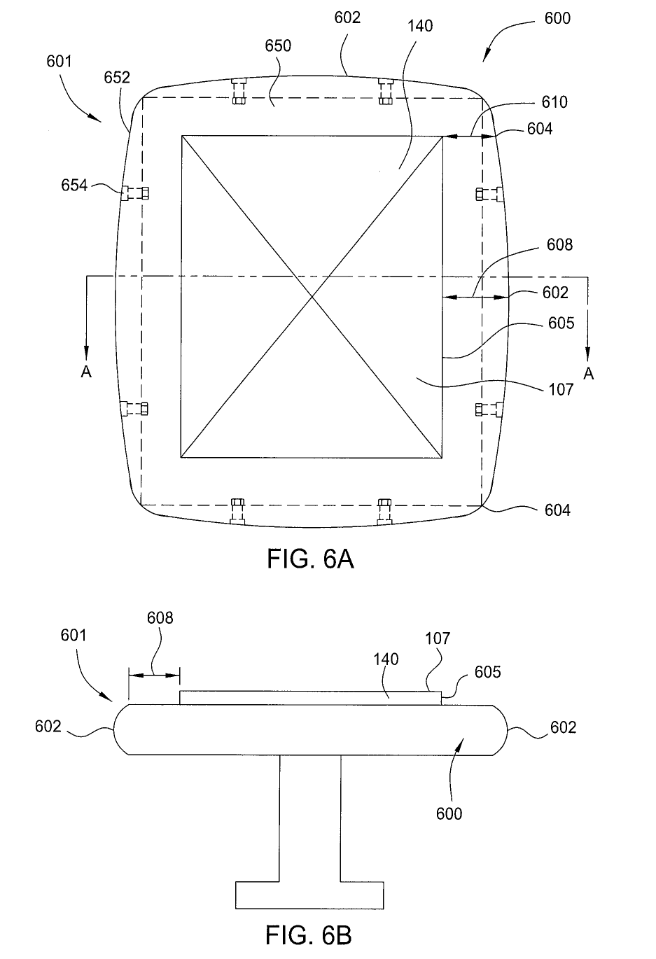

Similar to the concept above, the enhanced corner flow may also be achieved by utilizing different outer perimeter geometries formed in a substrate support, such as the substrate support 600 depicted in FIGS. 6A-6B, or even in the sidewall 102 of the processing chamber 100. The substrate support 600, similar to the substrate support 130 described above but with different outer perimeter geometry, may have a substantially quadrilateral configuration having four sides 601 with a desire curvature formed in the substrate support 600. By selecting an appropriate curvature of the sides 601, the gap between the perimeter of the substrate support 600 and the sidewall 102 of the processing chamber may be varied so that more flow occurs at a corner region 604 relative to the center region 602, or at the center region 602 relative to the corner region 604, depending on the selected curvature. In the example depicted in FIG. 6A-6B, the substrate 140 is disposed on the substrate support 600. Each side 601 has a center region 602 and a corner region 604. The corner region 604 has a width 610 (e.g., from a sidewall 605 of the substrate 140 to the side 601 of the substrate support 600) shorter than a width 608 of the center region 602. The enhanced corner flow may be obtained by controlling the width 610 of the corner region 604 about 30% and about 90% less than the width 608 in the center region 602.

In another example, the substrate support 600 may be a conventional substrate support, such as the substrate support 130 depicted in FIG. 1 with a rectangular geometry, having a rectangular frame body 650 with a removable skirt 652 attached to the frame body 650. The removable skirt 652 may be attached to the frame body 650 by suitable fasteners 654. The removable skirt 652 may be configured to have different geometries, e.g., including asymmetric geometries, curvatures, apertures and the like, so as to preferentially control have much gas flows pass different periphery regions 107 of the substrate 140. As the pumping port 109 may be located at a certain side of processing chamber 100, as shown in FIG. 1, different pumping efficiency at different locations (e.g., sides) of the processing chamber 100 may result in asymmetric gas flow velocity or gas flow profile at different sides of the periphery region 107 of the substrate 140. By utilizing the removable skirt 652, the outer perimeter profile of the substrate support 601 may be changed so as to control the gas flow path or gas flow adjacent to the periphery region 107 of the substrate 140. For example, the shape of the skirt 652 may be selected to have a smaller gap with the processing chamber 100 proximate the pumping port 106 relative to the opposite side of the substrate support 601 so that the flow of gases around the periphery region 107 of the substrate support 601 and substrate 140 is substantially uniform. Furthermore, the removable skirt 652 may be optionally implemented around the on the substrate support 601 only certain sides (e.g., not all four sides of the substrate support 601) so as to obtain an asymmetric gas flow if desired.

FIG. 6B depicts a cross sectional view of the substrate support 600 cutting along the cut-alone line A-A. The center region 602 with a curved geometry has the predetermined width 608 distanced from the sidewall 605 of the substrate 140. As discussed above, the width 610 defined in the corner region 604 is less than the width 608 shown in FIG. 6B. It is noted that the enhanced corner flow can also be obtained by altering the geometry of the sidewall 102 of the processing chamber 100 to make the sidewall 102 of the processing chamber 100 curved in a manner that can generate different gas flow velocity/pressure to the substrate 140 as needed.

In summary, embodiments disclosed herein relate to frames with different outer perimeter geometries that may be utilized to alter or adjust gas flow path (i.e., the ratio of the gas delivered to the corner of the substrate relate to the substrate edge) velocity and process pressure provided across the substrate surface. By doing so, a uniform or non-uniform gas flow path may be selected for different process requirements or circumstances to obtain a desired gas distribution across the substrate surface so as to improve deposition or cleaning efficiency.

While the foregoing is directed to embodiments of the invention, other and further embodiments of the invention may be devised without departing from the basic scope thereof.

1. A frame, comprising:
a frame body having an inner wall and an outer wall;
a center opening formed in the frame body bounded by the inner wall; and
a corner region and a center region formed in a first side of the frame body, wherein the corner region has a corner width that is smaller than a center width of the center region, the widths defined between the inner and outer walls.

2. The frame of claim 1, wherein a difference between the center width to the corner width is between about 5 mm and about 60 mm.

3. The frame of claim 1, wherein the center width is between about 30% and about 90% larger than the corner width.

4. The frame of claim 1, wherein the frame body is fabricated from a conductive material.

5. The frame of claim 1, wherein the center opening has a quadrilateral form.

6. The frame of claim 1, wherein the outer wall has a geometry that preferentially directs more flow passing over the frame to a corner region or to a center region.

7. The frame of claim 1, wherein a portion of the outer wall in the corner region has a curvature and a portion of the outer wall in the center region is substantially linear.

8. A processing chamber, comprising:
a chamber body comprising a top wall, a sidewall and a bottom wall defining a processing region in the chamber body;
a substrate support positioned in the processing region, the substrate support having an outer profile selected to preferentially direct more flow passing between the substrate support and sidewall to a corner region relative to a center region or to the center region relative to the corner region;
a pumping port disposed through the bottom wall of the chamber body under the substrate support.

9. The processing chamber of claim 8, wherein a gap defined between the outer profile of the substrate support and the sidewall of the chamber body is different near the center region of the substrate support relative to the corner region of the substrate support.

10. The processing chamber of claim 8, wherein the substrate support comprises:
a frame disposed on the substrate support and circumscribing a substrate supporting surface defined on the substrate support, wherein the outer profile is defined by one of the substrate support or the frame.

11. The processing chamber of claim 10, wherein the frame further comprises:
a corner region formed in a first side of the frame, wherein the corner region has a corner width that is smaller than a center width of the center region, the widths defined between the inner and outer walls.

12. The processing chamber of claim 11, wherein the frame further comprises:
a difference between the center width to the corner width is between about 5 mm and about 60 mm.

13. The processing chamber of claim 10, wherein the gap has a first width defined between a corner region of the frame and the sidewall and a second width defined between the center region of the frame and the sidewall, wherein the first width is greater than the second width, the widths defined between the inner and outer walls.

14. The processing chamber of claim 13, wherein the second width is less than 10 mm.

15. The processing chamber of claim 14, wherein the center region of the first side of the frame is in close proximate to with the sidewall.

16. The processing chamber of claim 13, wherein the wherein the second width is between 10 mm and about 40 mm.

17. The processing chamber of claim 14, wherein the center region comprises a substantially liner surface of the outer wall and the corner region has a curved surface.

18. The processing chamber of claim 10, wherein the frame comprises an inner wall opposite to the outer wall defining a quadrilateral center opening.

19. The processing chamber of claim 10, wherein the frame is rectangular.

20. The processing chamber of claim 10, wherein the gap is narrow at the center region relative to the corner region.

21. A method of controlling a non-uniform gas flow in a processing chamber, comprising:
directing a deposition gas flow through a corner gap and a center gap defined between a frame and a sidewall of a processing chamber into a processing region defined in the processing chamber, wherein the gas flow has a first flow rate flowing through the corner gap that is greater than a second flow rate through the center gap.

22. The method of claim 21, wherein the frame circumscribes an edge of a substrate support in the processing region.

23. The method of claim 21, wherein the corner gap has a width greater than that of the center gap.
